(19) United States
(12) Patent Application Publication
(10) Pub. No.: US 2001/0034136 A1
(43) Pub. Date: Oct. 25, 2001

(54) METHOD FOR IMPROVING CONTACT RESISTANCE OF SILICIDE LAYER IN A SEMICONDUCTOR DEVICE

(76) Inventors: YIL WOOK KIM, ICHON-SHI (KR); JAE YOUNG KIM, ICHON-SHI (KR)

Correspondence Address: JACOBSON PRICE HOLMAN & STERN, 400 SEVENTH STREET NW, PROFESSIONAL LIMITED LIABILITY COMPANY, WASHINGTON, DC, 20004

(21) Appl. No.: 09/336,712

(22) Filed: Jun. 21, 1999

(30) Foreign Application Priority Data
Jun. 23, 1998 (KR) 1998-23613

(51) Int. Cl. H01L 21/302; H01L 21/461

(52) U.S. Cl. 438/712

(57) ABSTRACT

A manufacturing method of semiconductor device of the present invention improves the contact resistance at silicide film while preventing junction region from being damaged, by simple process performed after contact etch. The method comprises a first step for forming an insulating film over a semiconductor substrate having, at least, silicide film at one part and junction region at another part; a second step for selectively etching the insulating film so as to expose both the silicide film and the junction region, in which a side effective film is undesirably formed on the silicide film and a third step for processing by plasma using inert element (e.g. Ar) containing gas in order to remove the side effective film ion the silicide film.

### BACKGROUND OF THE INVENTION

The present invention relates to a method for manufacturing a semiconductor device for improving contact resistance, more particularly to a post-process, which is performed after an etch process for opening a plurality of contact holes through a silicide layer included in the semiconductor device.

The line width becomes narrower due to the high integration of the semiconductor device. In contrast, the semiconductor device is required to be operated at higher speed. Thus, at present, a composite layer composed of a doped polysilicon layer and a silicide layer is much more desirable than a single conductive layer composed of single doped polysilicon layer. For example, as word lines and the bit lines in a semiconductor memory device, so-called “polycide”, is usually used, which is formed by sequentially depositing a polysilicon layer and a silicide layer. It is well known that a single silicide layer is not preferable to be used as a conductive layer due to the bad adhesiveness to other films, e.g. an insulating film which is typically composed of silicon dioxide(SiO₂).

In the meantime, a contact opening process, in which two types of contact holes are simultaneously opened, should be performed in a semiconductor memory device. One type of contact hole is for exposing the surface of a gate electrode composed of polycide and the other type of contact hole is for exposing the surface of the junction area, e.g. source/drain region. This contact opening process causes problems, which will be explained with reference to FIGS. 1 and 2.

FIG. 1 illustrates a cross sectional view of a semiconductor device, in which the contact holes 15a and 15b are formed by simultaneously etching the interlayer insulating layer 14 to expose both the surface of the gate electrode composed of the polysilicon layer 11 and the tungsten silicide 12 and the surface of the junction(e.g. source/drain region).

However, the carbon component generated during the etching process for opening the contact holes, the oxygen component generated from the interlayer oxide layer 14 or during the removing process of a photoresist pattern and the metal component(e.g. tungsten(W)) of the silicide layer 12 are coupled so that an insulating layer 16, which pertains to W—O—C group, may be formed on the surface of the tungsten silicide film 12, with very low thickness, e.g. 100 Å. Such an insulating film 16 is so consolidated as not to be removed by etchant for oxide film, e.g. BOE, HF, and etc. As a result, there is a problem in that the water-containing washing after the etch process for contact hole formation would not remove the insulating film 16. Also, the carbon(C) of carbon fluoride typically used for etching of the contact hole formation is injected into the polycide film so that a schottky barrier is made at the boundary, thereby also increasing the contact resistance. Thus, while the contact resistance at the boundary of the junction region 13 is low, the contact resistance at the boundary of the silicide film is very high due to the resistance of the thin insulating film 16 and the schottky barrier by the carbon element. Accordingly, for removing the insulating layer 16, over-etch is required during the etching process for opening the contact hole, which also causes damage of the surface of the junction region 13.

FIG. 2 is for illustrating another conventional technology for improving the contact resistance characteristic at the gate electrode without the damage of the junction region.

As shown in FIG. 1, the interlayer insulating layer 14 is etched so that the contact holes 15a and 15b are formed. Then, a sacrifice film 17 is deposited onto only the contact hole 15b located at the junction region 13. Here, the sacrifice film 17 is formed by exposing the contact hole 15b through photolithography process and then depositing an insulating material such as oxide or organic material such as photoresist material. Subsequently, the photoresist pattern for the deposition of the sacrifice film 17 is removed, and then the silicide film 12 is etched, for example using Cl₂ based gas or Cl₄ based gas. The sacrifice film 17 is used for preventing the junction 13 from being damaged during the etching process for the silicide film, in which the damage is due to the similarity of the etching selectivity between the silicide and the silicon.

However, this improved conventional technology has another problem in that the manufacturing process is so complex that the yield and the productivity should be decreased since the sacrifice film 17 requires additional processes.

### SUMMARY OF THE INVENTION

The present invention is devised for solving the above problems. The object of the present invention is to provide a method for manufacturing a semiconductor device for improving the contact resistance characteristics to silicide layer.

Also, the other object of the present invention is to provide a method for manufacturing a semiconductor device for improving the contact resistance characteristics to silicide, while preventing the junction region from being damage by means of simple process.

According to one aspect of the invention for accomplishing the Above object, there is provided a manufacturing method of semiconductor device, comprising: a first step for forming an insulating film over a semiconductor substrate having, at least, silicide film; a second step for selectively etching the insulating film so as to expose, at least, a part of the surface of the silicide film, wherein said second step for selectively etching undesirably produces a side effective film (or undesirable film) on the silicide film; and a third step for processing by plasma using inert element containing gas in order to remove the undesirable film on the silicide film generated in the second step.

The third step can be made such that the undesirable film can be physically removed by inert gas plasma process. Also, the third step is made such that the undesirable film can be physically and chemically removed by composite gas plasma process, the composite gas including an inert gas and, at least, one selected from the group of oxygen element(O) containing gas, nitrogen element(N) containing gas, oxygen(O₂) gas, nitrogen(N₂) gas. The insulating film may comprise, at least, one oxide film.

The second step may include the steps of: forming a photoresist pattern on the oxide film as etch mask; etching the oxide film; and removing the photoresist pattern. The side effective film may be an another insulating film including, at least, carbon element. The silicide film may be tungsten silicide film and the undesirable film May be composed of W—O—C group material. The etching in the second step can be performed by dry etch, and the plasma processing in the third step may be preferably performed in-situ in the same equipment sphere the etching has been performed.

The inert gas used for plasma process may be one or more selected from the group of Ar, He, Ne and Xe.

In accordance with another aspect of the present invention, there is provided a manufacturing method of semiconductor device, comprising: a first step for forming an insulating film over a semiconductor substrate having, at least, silicide film at one part and junction region at another part; a second step for selectively etching the insulating film so as to expose both the silicide film and the junction region, the etching undesirably producing an undesirable film on the silicide film; and a third step for processing by plasma using inert element containing gas in order to remove the undesirable film on the silicide film generated in the second step.

In the preferred embodiment, the third step is made such that the undesirable film can be physically removed by inert gas plasma process. Otherwise, the third step is made such that the undesirable film can be physically and chemically removed by composite gas plasma process, the composite gas including an inert gas and, at least, one selected from the group of oxygen element(O) containing gas, nitrogen element(N) containing gas, oxygen(O₂) gas, nitrogen(N₂) gas. The silicide film may be a tungsten silicide film and the Undesirable film is composed of W—O—C group material.

Also, the plasma treatment of this invention may be performed using a gas that does not include any carbon element, in order to suppress the generation of schottky barrier by carbon element. For example, the plasma treatment may be performed using at halogen gas such as Cl₂, NF₃ and SF₆. Otherwise, the plasma treatment may be performed using at least one of Cl₂, NF₃ and SF₆ and at least one of O₂, N₂ and Ar. More preferably the mixed gas of Ar and O₂ may be used in the plasma treatment.

According to still another embodiment of this invention, there is provided a method of manufacturing a semiconductor device comprising the steps of: forming a gate electrode on a semiconductor substrate, wherein said gate electrode includes a silicide film at the uppermost portion thereof; forming a source/drain region on the semiconductor substrate; forming an interlayer insulating film over the entire surface of semiconductor structure including said gate electrode and said source/drain region; selectively etching said interlayer insulating film to form contact holes that expose the surface of the silicide film of the gate electrode and the source/drain region, wherein the selectively etching for forming the contact holes also makes an undesirable side effective film on the silicide film; and performing a plasma treatment using a gas that does not include any carbon element, in order to remove the side effective film on the silicide film. The gas used in the step for performing a plasma treatment is preferably composed of Ar and O₂. Also, in order to suppress the generation of schottky barrier by carbon element the gas in the plasma treatment may be composed of at least one of Cl₂, NF₃ and SF₆. Further, it may be more preferably composed of at least one of Cl₂, NF₃ and SF₆ and at least one of O₂, N₂ and Ar.

### BRIEF DESCRIPTION OF THE DRAWINGS

For a more complete understanding of the present invention and the advantage thereof, reference is now made to the following description taken in conjunction with the accompanying drawings in which:

FIG. 1 is a cross sectional view of a semiconductor device after the contact holes are opened in accordance with a conventional technology;

FIG. 2 is a cross sectional view of a semiconductor device after the contact holes are opened in accordance with another improved conventional technology;

FIG. 3 is a cross sectional view of a semiconductor device, which is for illustrating a post process performed after the contact etch, in accordance with one preferred embodiment of the present invention;

FIG. 4 is a cross sectional view of a semiconductor device, which is for illustrating a post process performed after the contact etch, in accordance with another preferred embodiment of the present invention;

FIGS. 5a and 5b are SEM of the semiconductor device having performed the post-process as shown in FIG. 3; and

FIGS. 6a and 6b are SEM of the semiconductor device having performed the post-process as shown in FIG. 4.

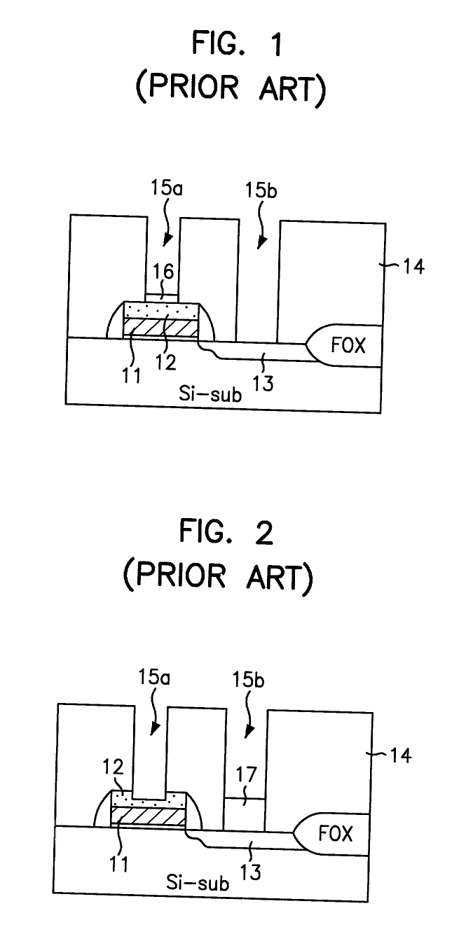

### DETAILED DESCRIPTION OF THE PRESENT INVENTION

Hereinafter, for explaining in detail in such a manner that the present invention may easily be carried out by a person having ordinary skill in the art to which the present invention, the preferred embodiments of the present invention will be described with reference to the accompanying drawings.

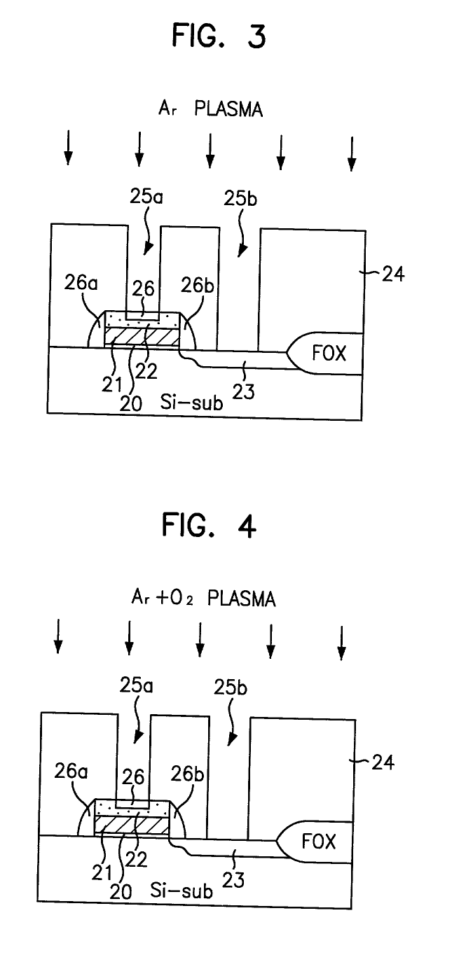

Referring to FIG. 3, the field oxide layer FOX, the gate electrode 21 and 22, the spacers 26a and 26b, the junction region 23 such as source or drain regions and the interlayer insulating layer 24 are formed using a conventional technology. Then, the interlayer insulating layer 24 is etched so that the contact hole 25a exposing the surface of the silicide film 22 and the contact hole 25b exposing the surface of the source/drain region 23 are simultaneously formed. One preferred method among the methods, which can be used for the above process, will be in detail explained as follows. The field oxide layer FOX is formed on the semiconductor substrate and then the gate oxide film 20 is formed on the active region. Subsequently, the materials constituting the gate electrode, for example an impurity(e.g. boron ion) doped polysilicon film 21 and a silicide film 22 such as tungsten silicide, are sequentially deposited on the gate oxide film 20. As well known to this art, the tungsten silicide film can be formed by so-called a silicide process, which is composed of depositing a tungsten film on the polysilicon film and then performing thermal process. The tungsten silicide film can also be formed by directly depositing the tungsten silicide material.

Here, ARC silicon nitride (SiON) film may be further formed over the silicide film 22 according to another preferred embodiment. Also, another oxide film or another nitride film can be further deposited over the silicide film 22, as a capping layer or a mask layer in accordance with still another preferred embodiment. In addition, ARC silicon nitride film can be further deposited over the mask oxide film.

Subsequently, a photoresist pattern for defining the gate electrode is formed through photolithography. Then, using the photoresist pattern for defining the gate electrode, the polysilicon film 21 and the silicide film 22 are patterned so that the gate electrode should be formed. Then, primary ion implantation is made for forming LDD structured source/drain region 23. This primary ion implantation is performed, for example, such that a low density of boron ion is implanted for p-type source/drain region. Then, the spacers 26a and 26b are formed at the sides of the gate electrode by depositing an insulating layer such as silicon dioxide over the entire substrate and anisotropically etching. Using these spacers and the gate electrode, a secondary ion implantation is performed for forming the LDD structured source/drain region 23. This secondary ion implantation is made, for example, such that the high density of boron ion is implanted for p-type source/drain.

Then, the interlayer insulating layer 24 is formed by conventional method. One preferred method for forming the interlayer insulating layer 24 is explained as follows. First, undopped silicon oxide film is formed over the entire wafer surface and then a dopped oxide layer such as BPSG, BSG and PSG for planarization is formed aver the undopped silicon oxide film.

After the formation of the interlayer oxide layer 24 as such, a photoresist pattern (not shown) for defining the contact holes is formed by photolithography. Using the photoresist pattern, the interlayer oxide layer 24 is etched so that the contact holes 25a and 25b are formed. After the formation of the contact holes 25a and 25b, the photoresist pattern for the contact holes 25a and 25b is removed.

Due to the above processes, an insulating film 26, which belongs to W—O—C group, is undesirably formed by side effect.

FIG. 3 is a cross sectional view of a semiconductor device, which illustrates the special characteristics in the fabricating method in accordance with one preferred embodiment of the present invention. In this figure, the insulating film 26 pertained to W—O—C group, which is generated after the contact etch process, can be removed by the physical attack using Ar-containing plasma. The Ar gas is an inert gas which would not react to the silicide film 22 or the silicon included in the junction of the source/drain region. This Ar gas can be substituted by inert gas such as He, Ne or Ne, so that the insulating film 26 can be removed by these substituted gas plasma. Here, this Ar plasma process can be performed in-situ in the etch equipment in which the previous etch process for forming the contact holes 25a and 25b has been performed. In other embodiment, this plasma process can be performed ex-situ for improvement of the equipment usage. Also, the Ar plasma can be generated by means of RIE type equipment, ICP or TCP equipments. In addition, the Ar plasma can be generated by means of High density plasma equipment such as Helicon, Helical or ECR type, or by means of Parallel Plate type equipment.

FIG. 4 is a cross sectional view of a semiconductor device, which illustrates the special characteristics in the fabricating method in accordance with another preferred embodiment of the present invention. This is devised because the junction surface is still physically damaged even in small degree during the plasma process using only Ar plasma. Thus, the insulating film 26 can be preferably removed using the plasma of the composite gas containing both Ar and O. If the Ar is added with O, the carbon component generated in resolving the insulating film of W—O—C group should be coupled to the oxygen component of the plasma, which becomes co₂ in turn. Thus, the insulating film 26 of W—O—C group can be much easier removed by this post etch process. Also, the added oxygen is coupled to the silicon at the surface of the junction region 23 so as to form the Si—O bonding, which prevents the silicon at the junction region from being striped off by the Ar plasma impact. In other words, the damage of the junction can be prevented. Further, even when the nitrogen(N) containing gas, or the oxygen(O)+nitrogen(N) containing gas in stead of the oxygen(O) containing gas, are added to the Ar gas, the substantial same effect can be acquired. Also, ,the oxygen gas(O₂), the nitrogen gas(N₂), or the composite gas of oxygen and nitrogen(O₂+N₂), in stead of the oxygen(O) containing gas, can be added to Ar.

In another preferred embodiment, instead of Ar, inert gas such As He, Ne, Xe or so can be used. Also, O₂ gas, N₂ gas, the composite O₂+N₂ gas, oxygen element containing gas, nitrogen element containing gas, or oxygen+nitrogen element containing gas are added to the inert gas, so as to produce the plasma for the post process of the contact hole etch.

In accordance with still another embodiment, the plasma is made of the gas that does not include any carbon element in order to prevent the schottky barrier by carbon element from being formed. For example, the plasma process of this invention may be performed using at least one of Cl₂, NF₃ and SF₆ or using at least one of Cl₂, NF₃ and SF₆ and at least one of O₂, N₂ and Ar.

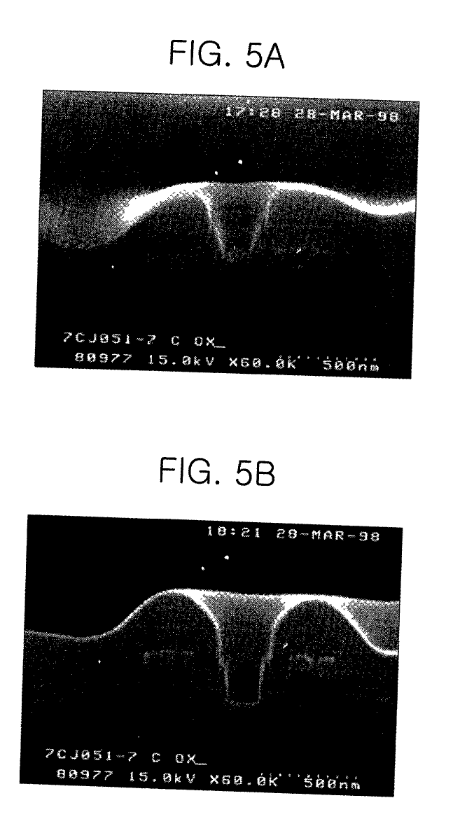

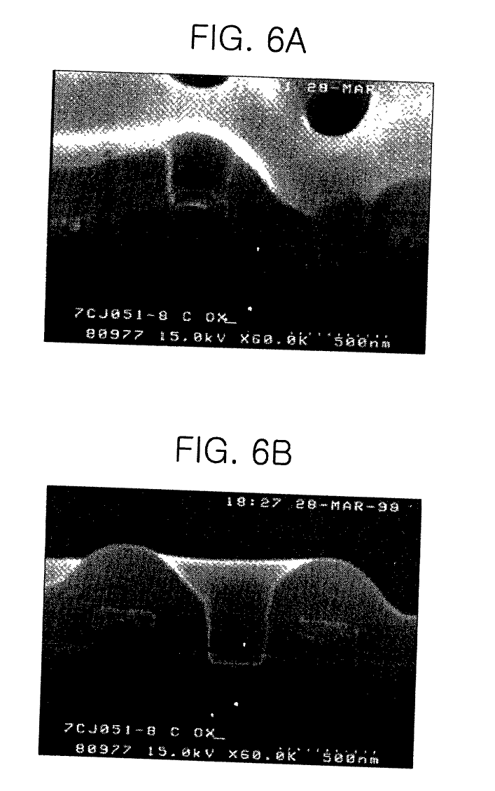

FIGS. 5a and 5b are SEMs for showing the profile of the contact holes at the polycide gate and the junction region of the semiconductor device, which is post-processed by Ar plasma after the contact hole etch, according to the method explained with reference to FIG. 3. FIGS. 6a and 6b are SEMs for showing the profile of the contact holes at the polycide gate and the junction region of the semiconductor device, which is post-processed by Ar+O plasma after the contact hole etch, according to the method explained with reference to FIG. 4.

The following table shows the variation of the measured contact resistance according to various conditions, in which the reference characters #1 and #2 represent the wafers without any post process after contact hole etch and the reference characters #3 and #4 Represent the wafers post-processed by Ar+O₂ plasma after contact hole etch.

| | | P2C/ | P2C/ | P2C/ | P2C/ | P2C/ |
|---|---|---|---|---|---|---|
| | SPLIT | P1_K | P1_CH | P1_CH | P1_CH | P1_CH |
| WAFER | CONDI- | 0.4 * | 0.45 * | 0.4 * | 0.35 * | 0.3 * |
| NUMBER | TION | 0.45 | 0.5 μm | 0.45 μm | 0.4 μm | 0.35 μm |
| #01 | BASE | 246 | 4768 | 6317 | 8580 | 13213 |
| #02 | | 241 | 4651 | 6198 | 8414 | 12876 |
| #03 | P2 DEP. | 233 | 6208 | 8238 | 13152 | 23787 |
| #04 | AFTER | 240 | 6483 | 8629 | 14053 | 24276 |
| | RTP | | | | | |
| #05 | P2 DEP. | 106 | 264 | 383 | 655 | 2520 |
| #06 | BEFORE | 207 | 1403 | 1904 | 2688 | 4885 |
| | RTP | | | | | |
| #07 | Cl₂O₂ 10 | 203 | 4633 | 6078 | 8183 | 13506 |
| #08 | Cl₂O₂ 20 | 161 | 2910 | 5003 | 8615 | 16751 |
| #09 | Cl₂O₂ 30 | 167 | 917 | 1308 | 2125 | 4864 |
| #10 | Cl₂O₂ 40 | 171 | 956 | 1276 | 1837 | 3295 |
| #11 | Ar 20″ | 273 | 866 | 1007 | 1400 | 3376 |
| #12 | Ar 40″ | 255 | 2434 | 3752 | 6276 | 9976 |
| #13 | Ar + O2 20″ | 236 | 597 | 692 | 885 | 1326 |
| #14 | Ar + O2 40″ | 206 | 353 | 410 | 521 | 607 |
| #15 | HF + H₂O₂ | 236 | 7200 | 9450 | 12584 | 17266 |
| #16 | | 220 | 5731 | 7620 | 10092 | 14023 |
| #17 | SC 1 | 312 | 5449 | 7552 | 10678 | 15976 |
| #18 | | 320 | 6881 | 9550 | 13521 | 19873 |
| #19 | HF + HCl | 168 | 1654 | 2250 | 3169 | 4576 |
| #20 | | 158 | 1411 | 1913 | 2677 | 3866 |

As shown in the above table, the contact resistance is reduced in the semiconductor post-processed by Ar+O₂ plasma, compared with other semiconductors.

When the Al+O₂ plasma post process is performed, the recipe is as follows:

(1) In RIE(Reaction Ion Etch), MERIE type equipment,

The pressure: 10˜1000 mTorr

Power: 100˜3000 W

The quantity of Ar gas : 1˜2000 sccm

The quantity of O₂ gas: 10˜100% of the quantity of Ar gas

(2) In ICP type equipment,

The pressure: 1˜20 mTorr

Source Power: 100˜3000 W

Bias Power: 100˜3000 W

The quantity of Ar gas: 1˜2000 sccm

The quantity of O₂ gas: 10˜100% of the quantity of Ar gas

As described above, the present invention can remove the undesirable insulating film formed over the silicide film due to the contact etch by simple process, so as to improve the contact resistance of the silicide film without any damage to the surface of the junction region. Particularly, the present invention can remove the undesirable insulating film formed over the silicide film without any damage to the surface of the junction region, while it does not require any additive and complex processes such as sacrifice film formation. Thus the present invention can improve the characteristics of the semiconductor device, the productivity and the yield.

Although preferred embodiments of the present invention has been illustrated and described, various alternatives, modifications and equivalents may be used. Therefore, the foregoing description should not be taken as limiting the scope of the present invention which is defined by the appended claims.

What is claimed is:

1. A manufacturing method of semiconductor device, comprising:
a first step for forming an insulating film over a semiconductor substrate having, at least, silicide film;
a second step for selectively etching said insulating film so as to expose, at least, a part of the surface of the silicide film, wherein said second step for selectively etching undesirably produces an undesirable film on said silicide film; and
a third step for processing by plasma using inert element containing gas in order to remove the undesirable film on said silicide film generated in said second step.

2. The manufacturing method of semiconductor device in accordance with the claim 1, wherein said third step is made such that the undesirable film can be physically removed by inert gas plasma process.

3. The manufacturing method of semiconductor device in accordance with the claim 1, wherein said third step is made such that the undesirable film can be physically and chemically removed by composite gas plasma process, the composite gas including an inert gas and, at least, one selected from the group of oxygen element(O) containing gas, nitrogen element(N) containing gas, oxygen(O₂) gas, nitrogen(N₂) gas.

4. The manufacturing method of semiconductor device in accordance with the claim 1, wherein said insulating film comprises, at least, one oxide film.

5. The manufacturing method of semiconductor device in accordance with the claim 4, wherein said second step comprises the steps of:
forming a photoresist pattern on the oxide film as an etch mask;
etching the oxide film; and
removing the photoresist pattern.

6. The manufacturing method of semiconductor device in accordance with the claim 5, wherein said undesirable film is an insulating film including, at least, carbon element.

7. The manufacturing method of semiconductor device in accordance with the claim 1, wherein said silicide film is tungsten silicide film and the undesirable film is composed of W—O—C group material.

8. The manufacturing method of semiconductor device in accordance with the claim 1, wherein the etching in the second step is made by dry etch, and the plasma processing in the third step is performed in-situ in the same equipment where the etching has been performed.

9. The manufacturing method of semiconductor device in accordance with the claim 1, wherein said inert gas is, at least, one selected from the group of Ar, He, Ne and Xe.

10. A manufacturing method of semiconductor device, comprising:
a first step for forming an insulating film over a semiconductor substrate having, at least, silicide film at one part and junction region at another part;
a second step for selectively etching said insulating film so as to expose both the silicide film and the junction region, the etching undesirably producing an undesirable film on said silicide film, and
a third step for processing by plasma using inert element containing gas in order to remove the undesirable film on said silicide film generated in said second step.

11. The manufacturing method of semiconductor device in accordance with the claim 10, wherein said third step is made such that the undesirable film can be physically removed by inert gas plasma process.

12. The manufacturing method of semiconductor device in accordance with the claim 10, wherein said third step is made such that the undesirable film can be physically and chemically removed by composite gas plasma process, the composite gas including an inert gas and, at least, one selected from the group of oxygen element(O) containing gas, nitrogen element(N) containing gas, oxygen(O₂) gas, nitrogen(N₂) gas.

13. The manufacturing method of semiconductor device in accordance with the claim 10, wherein said silicide film is a tungsten silicide film and the undesirable film is composed of W—O—C group material.

14. The manufacturing method of semiconductor device in ,accordance with the claim 10, wherein said third step is a plasma processing using Ar and O₂.

15. The manufacturing method of semiconductor device in accordance with the claim 10, wherein said third step is performed using at least one of Cl₂, NF₃ and SF₆.

16. The manufacturing method of semiconductor device in accordance with the claim 10, wherein said third step is performed using at least one of Cl₂, NF₃ and SF₆ and at least one of O₂, N₂ and Ar.

17. A method of manufacturing a semiconductor device comprising the steps of:
forming a gate electrode on a semiconductor substrate, wherein said gate electrode includes a silicide film at the uppermost portion thereof;
forming a source/drain region on the semiconductor substrate;
forming an interlayer insulating film over the entire surface of semiconductor structure including said gate electrode and said source/drain region;
selectively etching said interlayer insulating film to form contact holes that expose the surface of the silicide film of the gate electrode and the source/drain region, wherein the selectively etching for forming the contact holes also makes an undesirable side effective film on the silicide film; and
performing a plasma treatment using a gas that does not include any carbon element, in order to remove the side effective film on the silicide film.

18. The method of the claim 17, wherein the gas used in the step for performing a plasma treatment is composed of Ar and O₂.

19. The method of the claim 17, wherein the gas used in the step for performing a plasma treatment is composed of at least one of Cl₂, NE₃ and SF₆. 20. The method of the claim 17, wherein the gas used in the step for performing a plasma treatment is composed of at least one of Cl₂, NF₃ and SF₆ and at least one of O₂, N₂ and Ar.
